(19) United States
(12) Patent Application Publication
(10) Pub. No.: US 2014/0312969 A1
(43) Pub. Date: Oct. 23, 2014

(54) POWER CONTROL

(71) Applicant: INDICE PTY LTD, Camberwell, Victoria (AU)

(72) Inventor: James Hamond, Kew (AU)

(21) Appl. No.: 14/351,262

(22) PCT Filed: Oct. 15, 2012
(86) PCT No.: PCT/AU2012/001246

§ 371 Date: Apr. 11, 2014

(30) Foreign Application Priority Data
Oct. 14, 2011 (AU) 2011904189

(51) Int. Cl. H03F 3/217

(52) U.S. Cl. CPC H03F 3/2176
USPC 330/251

(57) ABSTRACT

A Class E amplifier having a FET with a transistor (T2) connected via a serial “LC” circuit to the load, and connected to a supply voltage via a constant current source, the amplifier further including a resonant controller, wherein the resonant controller provides power control for an AC application and includes resonance tracking system of an input inductor being fed by a power source with the resonance tracking system using a resistor resonance detector having two sense resistor loads in series.

### FIELD OF THE INVENTION

This invention relates to power control and in particular to distinct control of switching to achieve power control. Even more particular the invention provides improved means of power control in silicon topologies but is not limited to such.

Whilst the invention may be applied to a range of power sources from low voltage to mains voltage and for Direct Current or Alternating Current (DC or AC), for convenience sake it shall be described herein in terms of a control of Light Emitting Diodes (LEDs) for a range of voltages. In particular it will be described with regard to a class E amplifier. However the scope of the invention is not limited thereto and can include one or more of the sections for other power control uses.

### BACKGROUND TO THE INVENTION

Important concerns in power control circuits are power loss and power storage. In switch-mode power supplies, power loss occurs in a variety of ways. Some of the dominant methods are:
1. Ohmic power P losses resulting from current I through a resistive R device described by the equation:

P=1²×R
2. When a switch such as a FET is transitioning from either on or off, and if either current or voltage was in or across the FET, the transition period will result in both current and voltage across said FET, equating to power loss.
3. Hard switching is the event where a FET, previously off and having voltage V across it, switches on. Parasitic capacitance C across the outputs will retain 30 energy E

E.0.5×C×V².
Each time the FET turns on under this condition the energy stored is dissipated as power loss.
4. Gate drive losses in the form of an equivalent RC circuit where the C is the gate capacitance, and the R is the connecting gate resistor. RC circuits dissipate power proportionally to the

Frequency F, capacitance C and Voltage V squared:

P=F×c×V²

One particular form of power control is the class E amplifier. A standard Class E amplifier is as shown in FIG. 1 and has a FET with a transistor (T2) connected via a serial “LC” circuit to the load (R1), and is connected to the supply voltage (not 5 shown) via a large inductor (L2). L2 acts as a rough constant current source. The class-E amplifier adds a capacitor (C1) across the transistor output leading to ground. However such a power amplifier incurs a number of power losses.

Accordingly, it is an object of the present invention to overcome or substantially ameliorate one or more of the disadvantages of the prior art or at least provide an effective alternative.

### SUMMARY OF THE INVENTION

The present invention provides a means and method of power control using state based control. The invention provides a number of different modifications that can be used separately or together.

The power control for an AC application can include resonance tracking system of an input inductor being fed by a power source wherein the resonance tracking system 20 uses a resistor resonance detector having two sense resistor loads in series to ground and receiving feedback of the input inductor between the two sense resistor loads with the first sense resistor load leading to ground and the second sense resistor load feeding to comparator to provide the output controlling drive signal in comparison to an input of a reference voltage.

It can be seen that the arrangement of the sense resistors loads are clearly a voltage summing node for the two respective signals. The first sense resistor load to ground can detect DC variations of input. The second sense resistor load feeding to comparator can detect AC fluctuations.

The feed to the comparator from the second resistor load can be modified by an RC filter.

The power control can include a brake circuit having detection means including RC circuit on voltage input feedback for ensuring no overcurrent.

The power control can include an active rectifier of input power to guarantee FET gate is within threshold in which there is a FET controller in combination with a linear regulator. The linear regulator can incorporate a large Resistor and small Zener voltage so as to minimise power losses through minimising current in control switching.

The power control can include a rectifier formed of a plurality of pairs of P and N doped MOSFETs wherein gate of one P doped MOSFETs is connected to drain of N doped MOSFET and vice versa. Preferably there are a pair of pairs of P and N 10 doped MOSFETs.

In this way operation of FETs with voltages of less than 1 Volt are still controlled by the rectifier. This also avoids punch through as operation of a pair of MOSFETs cannot occur at the same is impossible.

In one form of the invention there is provided with a state switching in regulation with switching in cycles being resonant and powered in compensation to each other to limit power usage and power losses.

The invention can provide substantial improvements in one form to an E class amplifier.

In a preferred embodiment the power control can relate to an E class amplifier and include any one or more of the following sections. These sections include:
A. Resonance tracking
B. Brake Circuit
C. Rectifier
D. Step Down

However these sections could also be used in other power control systems to perform analogous benefits.

It can be seen that the invention provides in one form a new method of class E topology control is presented. Whilst self resonant, the new approach has little in common with other self resonant systems where FET drive controls are coupled from other components such as transformers. Problems with such applications include poorly defined start/stop conditions, as well as limited room for wave form control.

The proposed method embeds real time, cycle by cycle digital control in simple components, with design freedom and advantages. Multiple analogue signals of differing values and frequencies are summed and thresholded by a single point of comparison. The control of these parameters allows precise resonant control from DC through to the physical limit of the resonant circuit of a large range of input voltages, with extraordinary efficiency, speed, and power factor.

### BRIEF DESCRIPTION OF THE DRAWINGS

In order that the invention can be more readily understood a specific embodiment will be described by way of non-limiting example wherein:

FIG. 1 is a circuit diagram of a class E amplifier of the prior art;

FIG. 2 is a circuit diagram of a power control of the invention in the form of a resonant driver in use in a class E amplifier of an embodiment of the invention;

FIG. 3 is a circuit diagram of power control of one embodiment of the invention showing control with AC sense and no brake;

FIG. 4 is an operational trace of V and I of power control circuit of FIG. 3;

FIG. 5 is a circuit diagram of power control of one embodiment of the invention showing brake;

FIG. 6 is an operational trace of V and I of power control circuit of FIG. 5;

FIG. 7 is a circuit diagram of power control of one embodiment of the invention showing rectifier;

FIG. 8 is a circuit diagram of power control of rectifier of prior art shown for comparative purposes;

FIG. 9 is an operational trace of V and I of power control circuit of FIG. 8;

FIG. 10 is a circuit diagram of power control of one embodiment of the invention showing rectifier with active pulldown;

FIG. 11 is an operational trace of V and 1 of power control circuit of FIG. 10;

FIGS. 12 and 13 are N and P FET equivalent sub circuits respectively showing the details of FETS X1 to X4 of FIG. 10 in combination with linear regulator;

FIG. 14 is a circuit diagram of power control of one embodiment of add on voltage control element to load of the invention showing step down and flyback alternatives;

FIG. 15 is an operational trace of V and I of power control circuit using step down of FIG. 14 for 9V at 10 ms;

FIG. 16 is an operational trace of V and I of power control circuit of FIG. 15 at micro level.

### DESCRIPTION OF A PREFERRED EMBODIMENT OF THE INVENTION

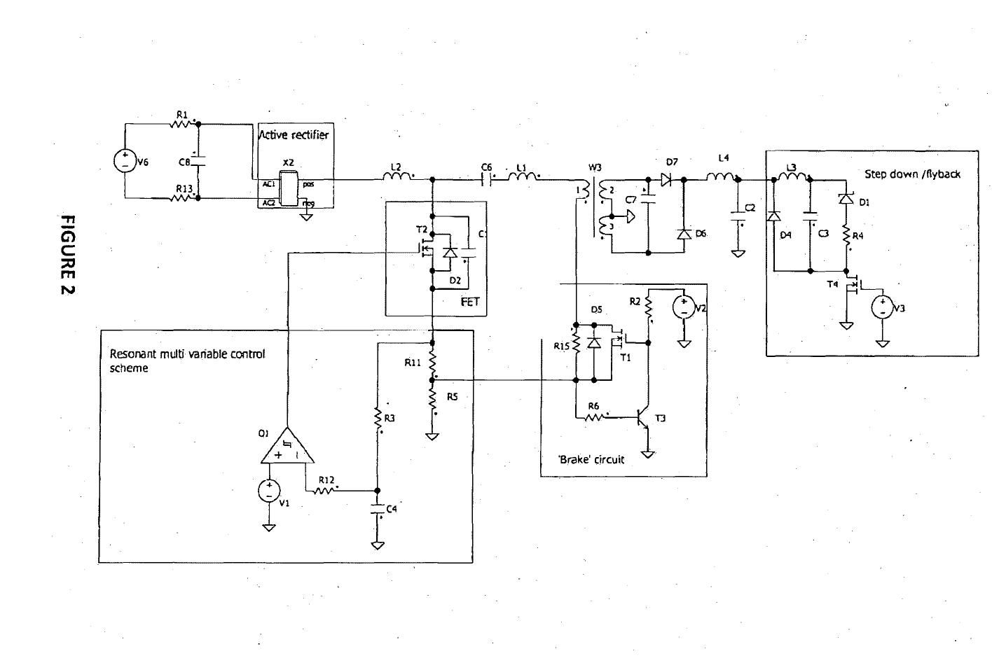

With reference to the drawings in this preferred embodiment, as shown in FIG. 2 the invention provides an E class amplifier having all sections of
A. Resonance tracking
B. Brake Circuit
C. Rectifier
D. Step Down/Fly Back

### A. Resonance Tracking

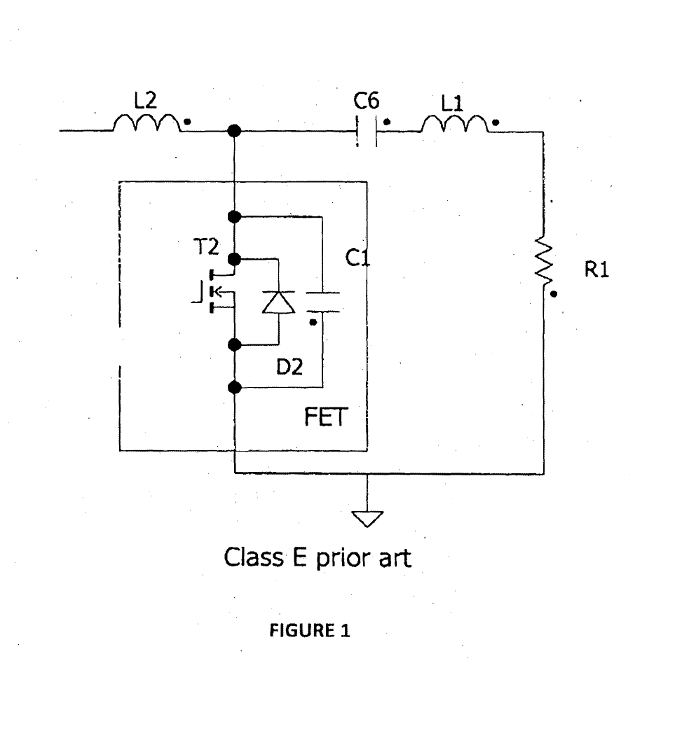

As shown in FIG. 1 one particular form of power control is the class E amplifier. A standard Class E amplifier has a FET with a transistor (T2) connected via a serial “LC” circuit to the load (R1), and is connected to the supply voltage (not shown) via a large inductor (L2), which acts as a rough constant current source.

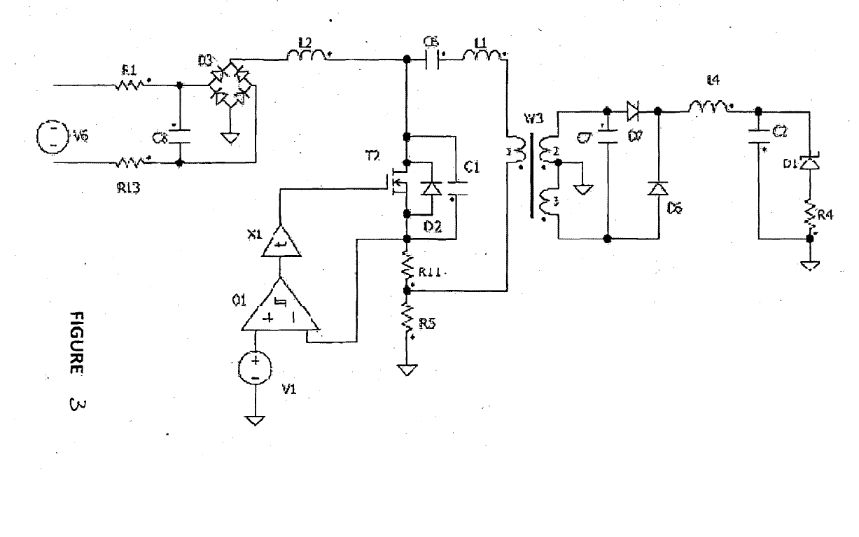

However expanding this to an AC application, either low or high voltage, is shown in FIG. 3. Here is the inclusion of the new resonant controller with components 01, V1 (reference voltage), R2 (resonance sensor) and R5 (input current sensor).

The power control for an AC application includes resonance tracking system of an input inductor being fed by a power source wherein the resonance tracking system uses a resistor resonance detector having two sense resistor loads in series. In this case the sense resistor loads are first and second sense resistors R5 and R11 to ground. Feedback of the input inductor L2 is received between the two sense resistor loads with the first sense resistor R5 leading to ground and the second sense resistor R11 feeding to comparator 01 to provide the output controlling drive signal in comparison to an input of a reference voltage V1.

It can be seen that the arrangement of the sense resistors loads are clearly a voltage summing node for the two respective signals. The first sense resistor R5 to ground can detect DC variations of input. The second sense resistor R11 feeding to comparator 01 can detect AC fluctuations.

The primary role of R5 is to track the desired current in L2. This way the system power can be controlled easily. Note that due to inevitable ripple current in L2, R5 does indeed contain ripple information. It is therefore feasible that normal operation can occur without the inclusion of R11. In practice, over the large voltage range imposed on the system by a rectified AC waveform, the necessity to amplify the ripple component becomes apparent. This is the point of R11; its inclusion ensures that adequate signal strengths is present. Note that the ratios of R11 and R5 also allow control of the system power factor.

Once the AC signal is adequate, it may be necessary to match the system resonance frequency with the digital system latencies. This can easily be achieved by the addition of optional phase lagging RC filters shown as R3 and C4 in FIG. 2. Additional latency control at the output of the comparator 01 may be performed in the digital section as needed.

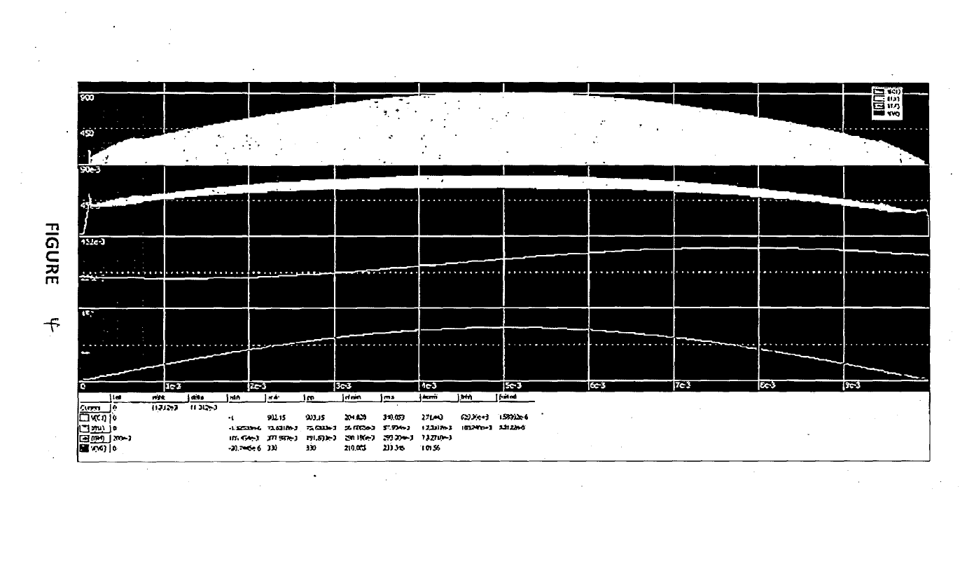

FIG. 4 illustrates how the above successfully ensures correct and regular operation 15 over 1 mains half cycle which in macro view illustrates how the system always Zero Voltage Switches (ZVS) paramount to high speed, low loss operation.

### B. Brake Circuit

With reference to the circuit of FIG. 3 with no brake, it can be seen that without a brake over current conditions can result in a variety of issues. AC signal is biased by DC ripple providing signal of resonance. Then this is slowed down by RC system including R12 and C4 thereby self resonating system. However if resonant and current pulsed are added there is the overcurrent condition and failure. This is a major source of concern and prior art solutions use substantial power.

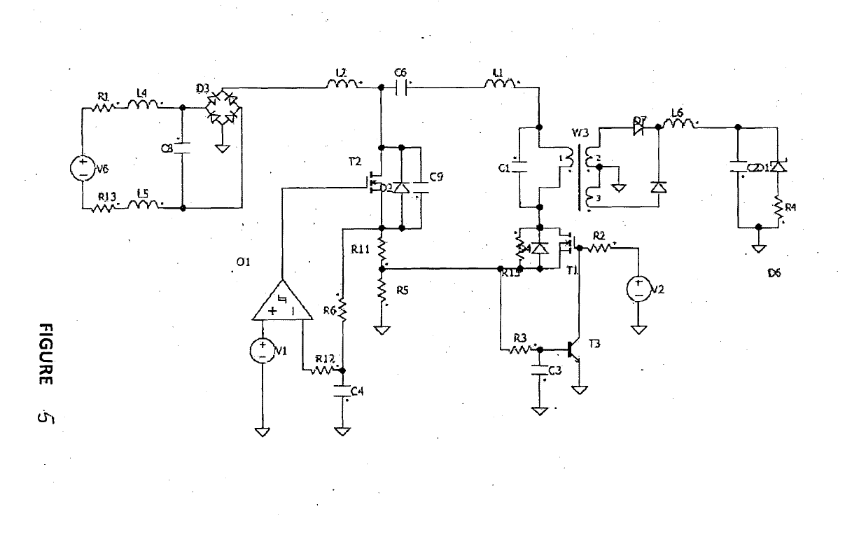

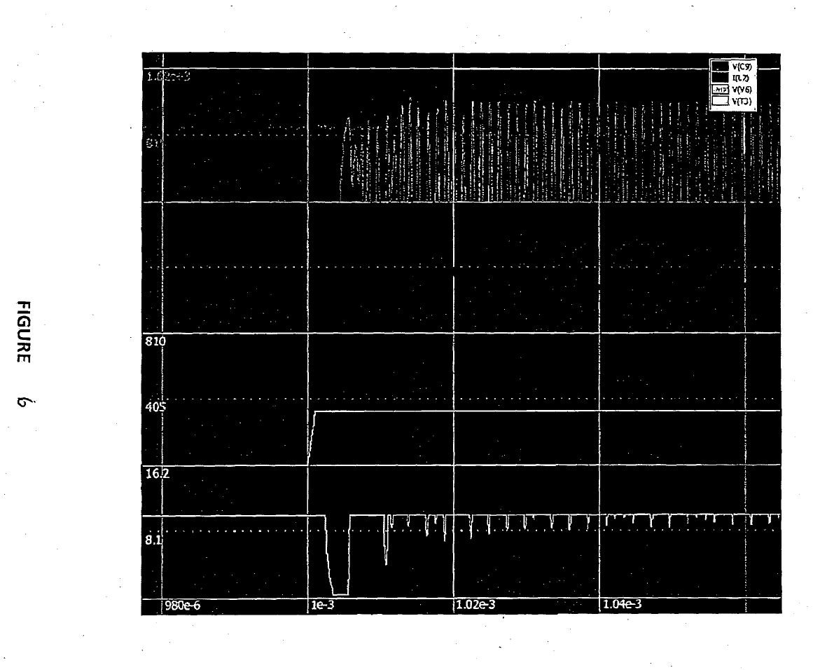

The circuit with brake is shown in FIG. 5 with brake elements provided by R3 and transistor. T3. In other form shown in FIG. 2 the R6 and T3 provide the brake element. An important effect is that the brake element turns off FET of T1 if overshoot allowing flow through R15. With reference to FIG. 5 and operational trace in FIG. 6 it is shown that there is provided stoppage means or brake for any overcurrent. In particular switching occurs only after powering off of other signal control and thereby avoiding possibility of overcurrent.

### C. Rectifier

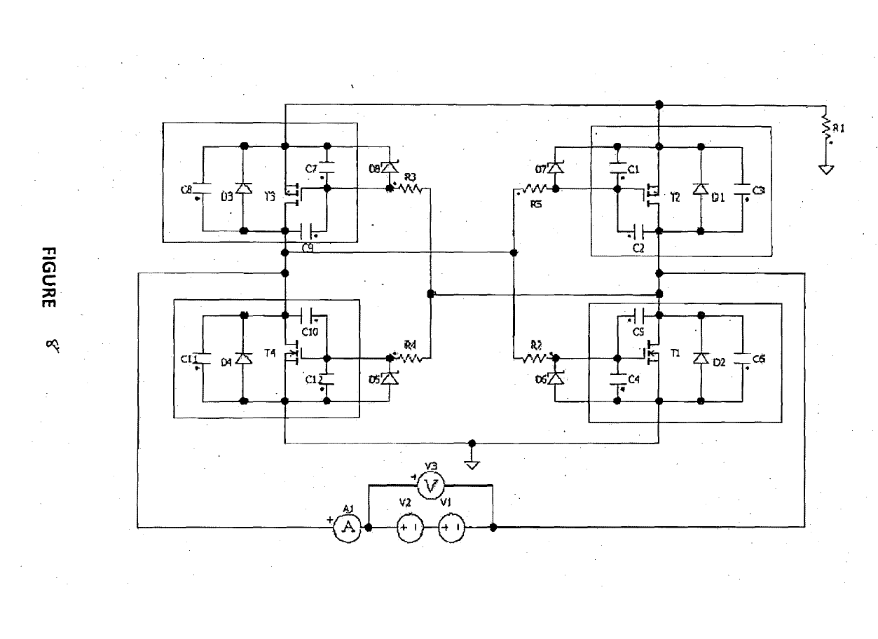

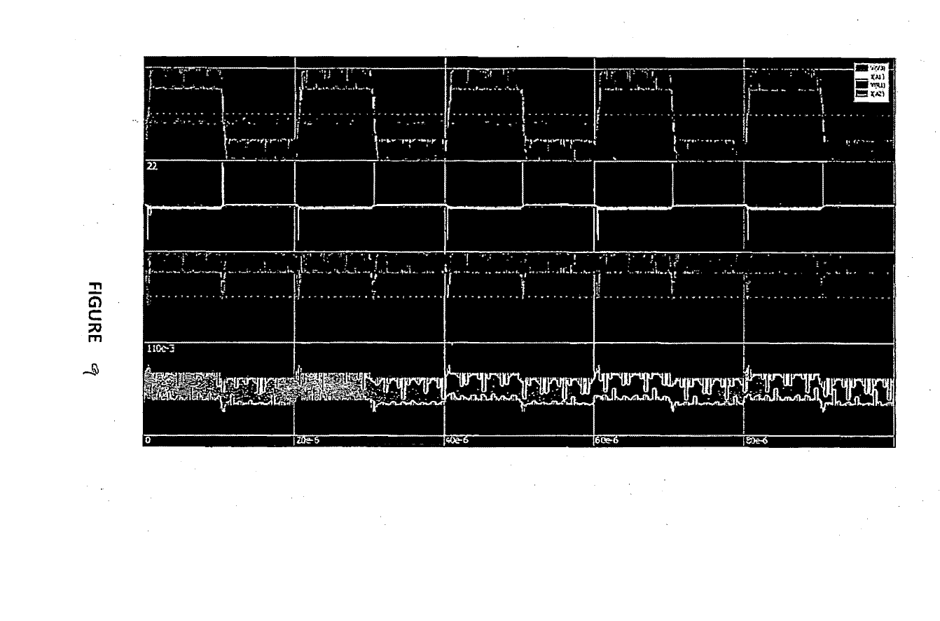

A prior art active rectifier circuit can be seen in FIG. 8 with operational trace in FIG. 9. In particular the FETs being either A type or N type are connected to external resistors such as R4 which are of the order of 100 Ohm and therefore allow substantial current flow and corresponding power loss. In particular the trace of FIG. 9 shows the input at the top and the effective output in the middle. However as shown by the lower trace there is substantial power losses throughout operation.

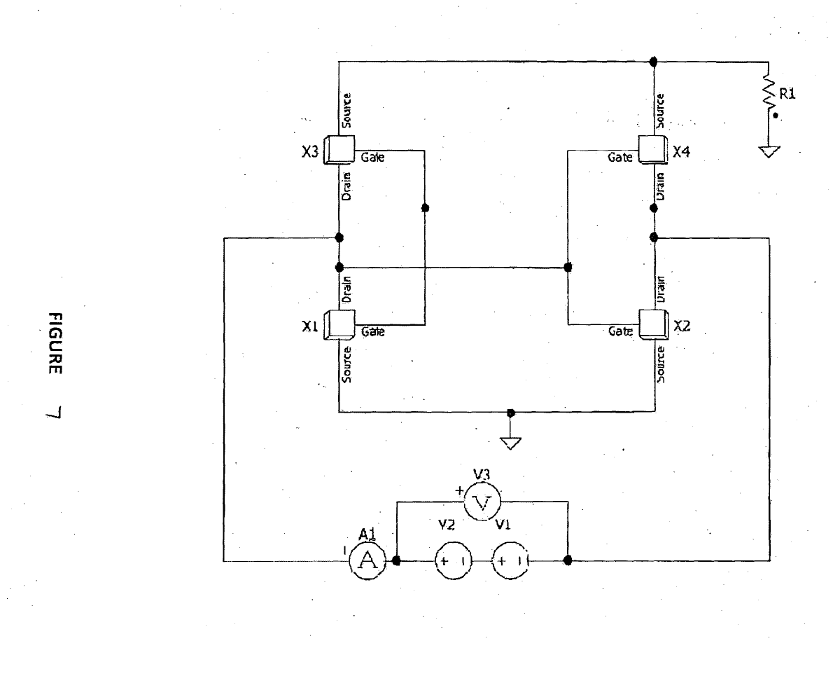

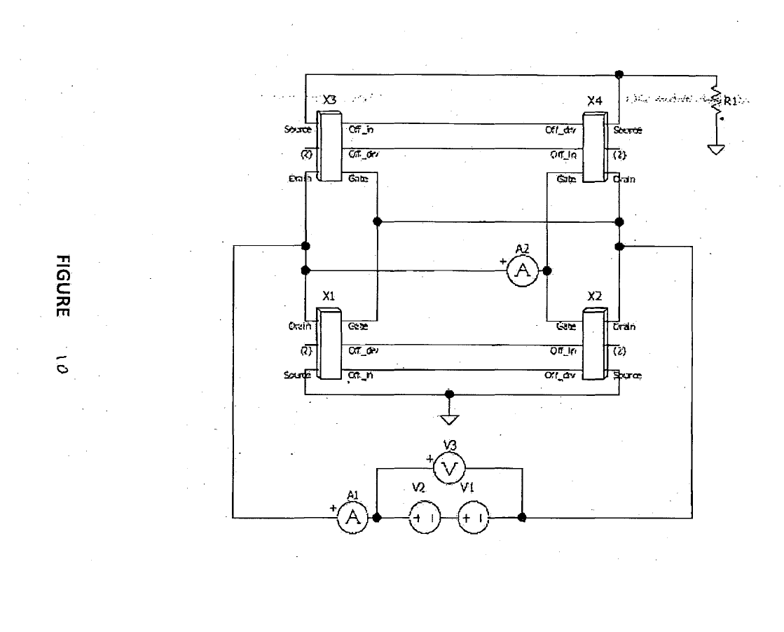

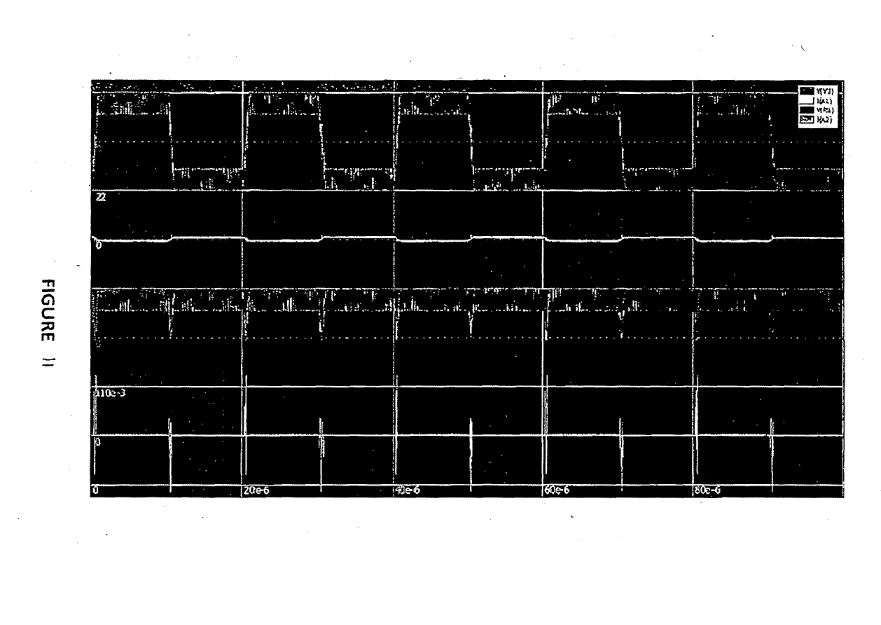

However the invention as shown in FIGS. 7 in its simplest form and FIGS. 10, 12 and 13 in detail with trace in FIG. 11 shows a rectifier which can make use of the power control including an active rectifier of input power to guarantee FET gate is within threshold. This is achieved by a FET controller in combination with a linear regulator. The linear regulator can incorporate a large Resistor R4 of the order of 100K Ohm′ and voltage close to operative voltage of the FET so as to minimise power losses through minimising current in control switching. In contrast to the trace of FIG. 9 the trace in FIG. 11 of the invention of FIG. 10 shows the input at the top and the effective output in the middle. However as shown by the lower trace there is minimal intermittent power losses throughout operation.

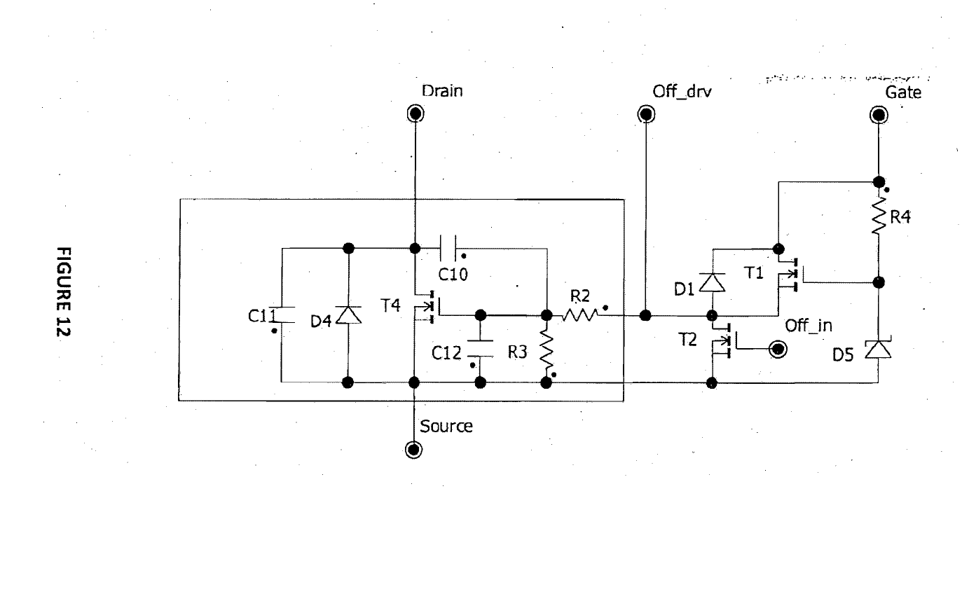

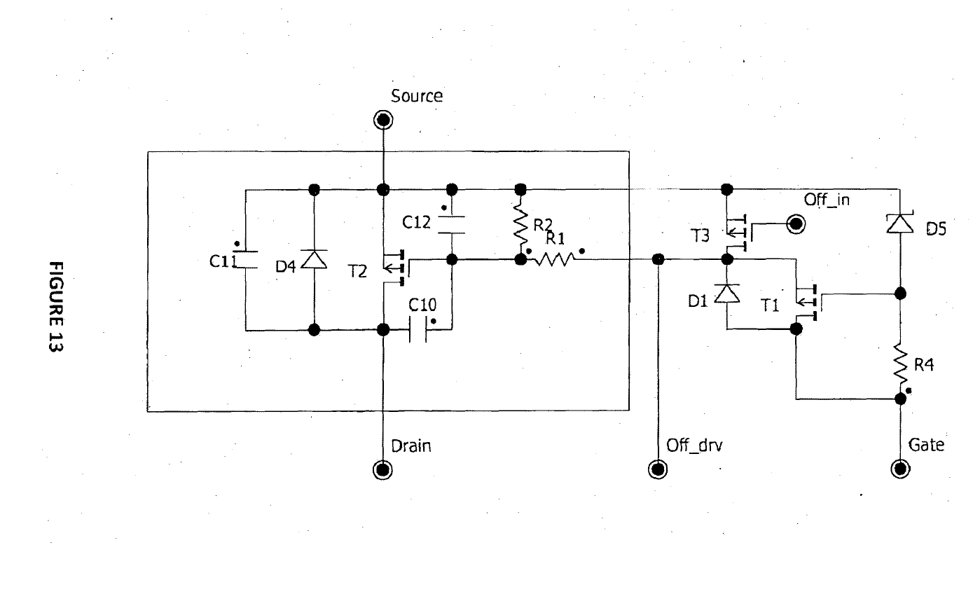

As shown in FIG. 10, the power control can include a rectifier formed of a plurality of pairs of P and N doped MOSFETs wherein gate of one P doped MOSFETs is connected to drain of N doped MOSFET and vice versa. In this case there are a pair of pairs of P and N doped MOSFETs with each of X1 to X4 comprising an NFET or PFET of FIGS. 12 and 13.

In this way operation of FETs with voltages of less than 1 Volt are still controlled by the rectifier. This also avoids punch through as operation of a pair of MOSFETs cannot occur at the same time and therefore cannot add voltages beyond threshold.

Particularly in low voltage, high current applications, AC to DC rectification can be more efficiently performed with a FET full bridge rather than diodes (Schottky, PN, carbide etc) as they need not have a forward conduction voltage drop anywhere near as large. There are some considerations in implementation:
1. If the maximum voltages exceed the FET gate values, protection must be implemented to ensure the MOSFETs are not destroyed. This is the purpose of the Zener/resistor arrangement in the schematic provided.
2. The Zener should be just slightly smaller than the max gate voltage, otherwise conduction through the Zener consume large amounts of energy, this unfortunately means that the gate capacitance has far more energy than is necessary to turn the FET on.
3. The resistor must be large enough to limit current when input voltage exceeds the Zener, but small enough to keep the turn on and off time small enough, and to prevent FET shoot through.
4. As MOSFETs have gate capacitance, any resistance used as with the example cause issues with turn on and turn off delay,
5. The gate capacitance and resistor form an RC filter, which will consume energy when any AC is present on the input, worsening with frequency and amplitude

The new configuration shown in FIG. 10 looks similar to the prior art of FIG. 8. However clear differences are shown with further inspection into the X modules is given in ‘SCH NFET basic’ and ‘SCH PFET basic of FIGS. 12 and 13. Each sub circuit (N and P) are designed to replace the MOSFET, Zener and resistor in the prior art, with the N's on the bottom, P's on the top of the bridge.

Examining the N FET subcircuit, the complete FET model is represented within the box. External to the Box is the added circuitry, a diode and FET (which would be only one device as MOSFETs always have body diodes) a resistor and a Zener. The addition of the MOSFET has a large impact on the circuit, such as:
1. The Zener can now be only large enough to ensure the rectifier FET is turned on, keeping the transfer of energy low.
2. The MOSFETs impedance is low during the charge of the bridge MOSFET, which allows for rapid charge, but becomes very high once the Zener voltage is reached, ensuring no leakage regardless of what AC signal is on the input.
3. As the Zener bias resistor is no longer charging the bridge MOSFET gate cap, its value can be very large, using very little energy.
4. When the gate signal pulls low, D1 (Ti's body diode) discharges the bridge gate capacitance.

The P FET subcircuit is identical in operation, just in a negative voltage sense as it is a P FET.

Referring to the Trace files of prior art FIG. 9 and new active rectifier FIG. 11, the red (top) trace shows a constructed wave form, a base signal of 12 VRMS (+−17 volt peak to peak) AC, with a 5 Vpp signal at much higher frequency. The next trace indicates the current from the source, the green is the voltage on the load resistor R1, the final trace is the current going into one half bridge P/N FET pair. The greatest indicator of improvement is the trace of FIG. 11, as is illustrated the new active rectifier has, with the exception of switching currents, no visible current. Measurements have indicated that with a simple comparison to FIG. 9, the new system is 98% efficient versus the old of 95%. This divide would become much greater over large input voltage ranges as the Zeners in the prior art conduct more and more, or if the frequency was increased.

Finally the next iteration of FIG. 10 shows an enhancement which allow the bridge FET's threshold voltage to be lower than the body diode of the new gate drive FET. Signals are shared between N and P subcircuits to ensure the FETs are shutdown.

In each N or P pair, the opposing drive FET now also drives the other's newly added ‘pull down’ FET.

### D. Step Down I Fly Back

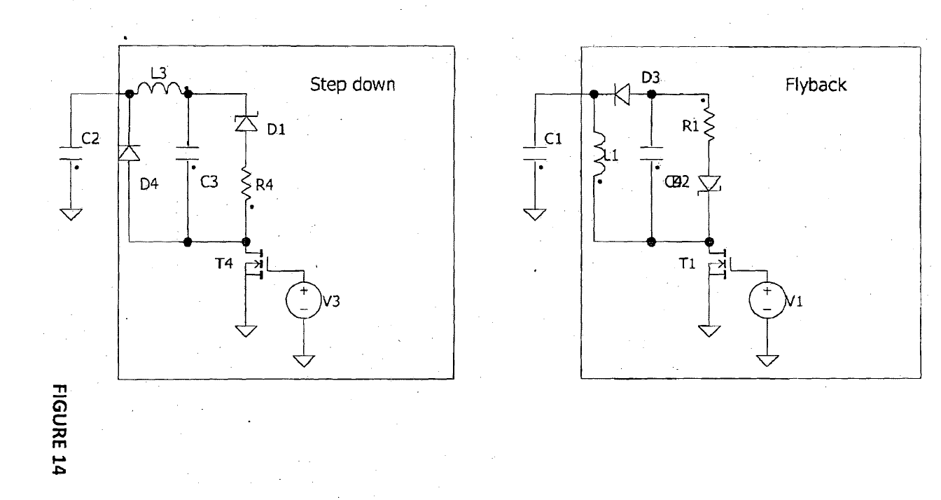

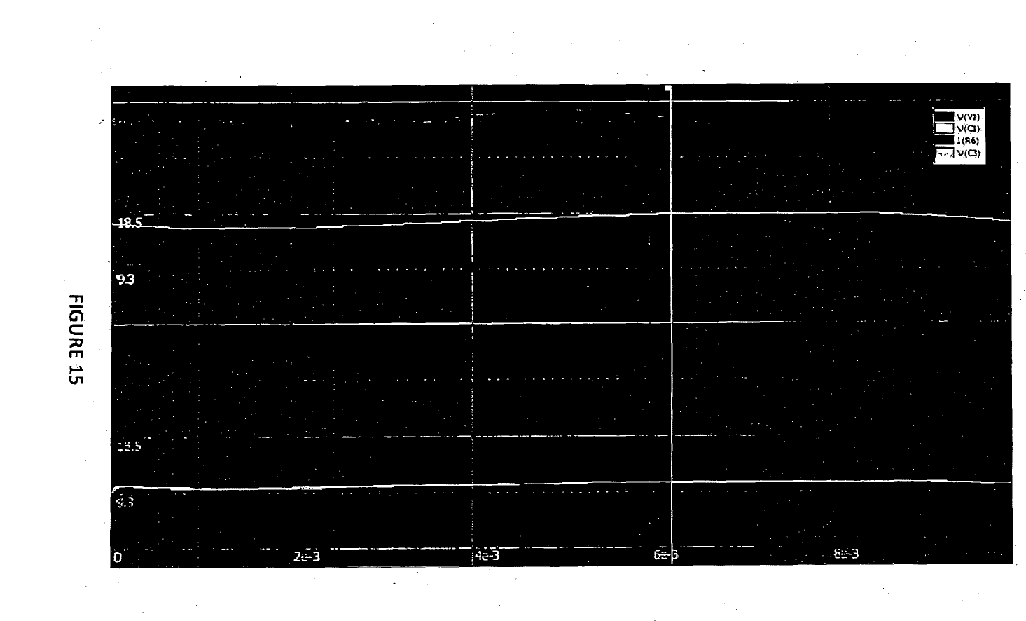

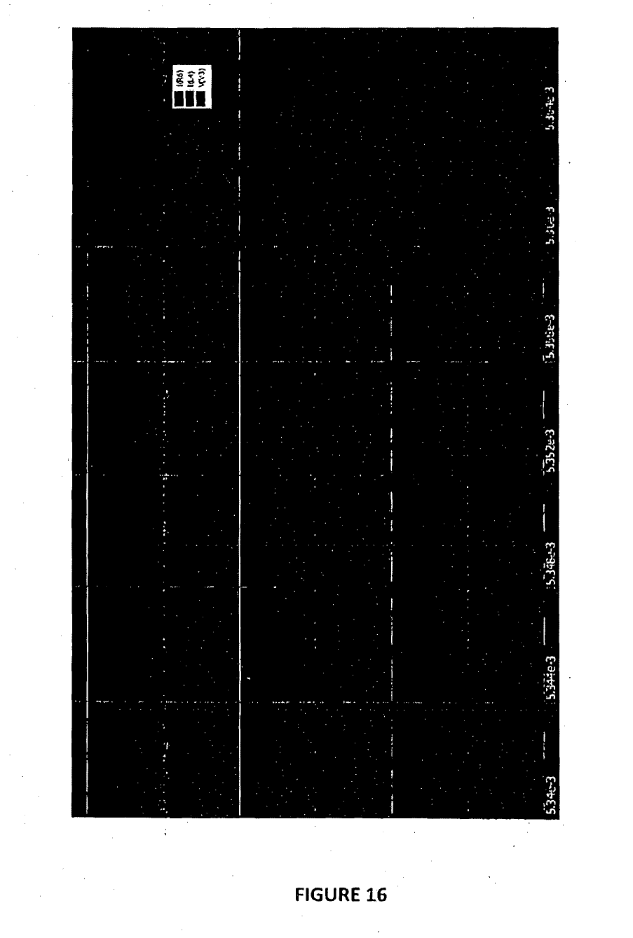

The step down/fly back component as shown in FIGS. 14 is often needed to connect at the output across Capacitor C2 as shown in FIG. 2 for power control of LEDs due to operational voltage limitation. However such system may not be required in other power control areas.

Due to the constant forward voltage nature of Light Emitting Diodes (LEDs) the usable energy in a capacitor connected in parallel is very limited. This is because any voltage in the capacitor above the LED Vf (forward voltage) is quickly discharged at higher currents, until the voltage falls to Vf, at which point conduction stops. A simple approach to this is to have a resistor in series, which limits the current at voltages over Vf. The drawback to this is of course wasted energy in the resistor.

A more elaborate method is to implement a full ‘buck’ circuit. Done well this can minimize the additional power loss, at the expense of complexity and cost. A potential issue with this is the introduction of a ‘negative impedance’—as voltage goes up, current-goes down and vice versa. This is in contrast to a ‘positive impedance’ which has current and voltage moving up and down together, proportionally or otherwise. In a standalone circuit a buck's negative impedance may not be an issue, but if used in conjunction with another control scheme this may become problematic.

Another problem with having a capacitor directly in parallel with a LED occurs when we are using a boost topology. As the output voltage must always be greater than the input voltage, LED Vf's must therefore be relatively high. In the case of MR16 where the input voltage can reach over 17V peak (12 VRMS) this limits the product to 20V+ dies. If we wish to use a lower voltage LED, a natural solution is to introduce a buck stage after the boost. However this introduces a problem where the individual boost and buck stages ‘fight’ each other, which is why despite the large capacitive energy reserve buffering between, the booster frequently turns off due to over voltage output conditions caused by a negative impedance load (the buck).

The present invention includes a much simpler step down mechanism to be introduced, which is much cheaper to implement, and still provides the boost with a positive impedance.

Referring to the FIG. 14, there is shown a general possible combination. These can be used for a 9V and a 21V LED solution. Even though the 21V LED already meets the greater voltage requirements, the ripple current in the LED over mains frequencies (50-60 Hz) is much better due to the more readily available energy reserve due to the large operational voltage range now available.

There are advantage of bucks in the prior art including allowing precise load regulation down to the load voltage if buck, or complete range if flyback. However there are also issues with bucks and flybacks including:
1. Expensive,
2. Complex closed loop systems and inefficient particularly if a high side FET drive is necessary (in buck configurations)
3. Imposes negative impedance characteristics on the voltage supply
4. Complexity and stability requirements generally limits maximum speed, which in turn requires larger passive components to implement

Similarly there are advantages of fixed frequency and duty step down or flyback
1. Open loop (no feedback) so very cheap and easy to implement
2. Only ever need low side switching so easy to implement
3. Imposes positive impedance at all times, easy to combine with regulation stage such as boost
4. Simplicity means that upper speeds are only limited by resonant source drive capabilities, so can be incredibly high.

Issues with fixed frequency and duty step down or flyback
1. Open loop means that operation is limited to fixed transformation of input voltage—ie no adaption possible.

The operation of the present invention is with reference to the drawings but noting that FIG. 14, R4 is included in series with D1 to represent a ‘real’ LED made up of desired and parasitic components. The Step down referred to in the 9V Schematic and Traces, has a very simple operation implements an oscillating source of any type capable of driving a FET, in this example V3. When the FET is biased on, current begins to rise in L3 the LED (D1) and C3. When the FET turns off, the inductor discharges into D1 and C3. C3 acts purely as an AC bypass to keep the current ripple in the LED to a minimum, and can therefore be extremely small. This simple action results in L3 appearing as an additional impedance in series with the LED, varying only with the difference in voltage between the LED Vf and the reservoir C3. This impedance can be varied by either changing the inductance of L1, or the frequency/duty cycle ratio of the inverter.

The flyback referred to in the 21V Traces and Schematics, as above the implementation is remarkably simple and also generally shown in FIG. 14. When the FET is biased on, L1 begins to charge. When the FET is turn off, L1 discharges into C4 and the LED. Again, C4 is included to merely bypass AC, providing DC current to the LED. This circuit differs to the step down in that it is possible to discharge C4 below the LED voltage. Whilst desirable with a large Vf such as 21 V, this is highly undesirable with voltages already lower than the minimum allowed boost voltage. As with the step down, the Inductor appears as a roughly linear, positive impedance, so long as the frequency and duty cycle ratio are fixed.

Note that any frequency and duty can be implemented, there are advantages to some adjustments, such as:
1. Frequency Jitter—this can help if Electro Magnetic Interference (EMI) are encountered
2. Duty cycles ratios other than 50/50 (as used in the examples) may be useful particularly if lower Vfs are desired, setting the duty to say 15/85 on/off would allow step down voltages as low as 3 Volts (single LED die) without adding any more complexity or feedback, depending on the oscillator source used.

While we have described herein a particular embodiment of a power control, it is further envisaged that other embodiments of the invention could exhibit any number and combination of any one of the features previously described. However, it is to be understood that any variations and modifications can be made without departing from the spirit and scope thereof

1. A Class E amplifier having a FET with a transistor (T2) connected via a serial “LC” circuit to the load, and connected to a supply voltage via a constant current source, the amplifier further including a resonant controller.

2. The amplifier according to claim 1 wherein the resonant controller provides power control for an AC application and includes resonance tracking system of an input inductor being fed by a power source with the resonance tracking system using a resistor resonance detector having two sense resistor loads in series.

3. The amplifier according to claim 2 wherein the resonant controller includes components reference voltage, resonance sensor and first input current sensor.

4. The amplifier according to claim 2 wherein the resonant controller includes sense resistor loads being first and second sense resistors R5 and R11 to ground with feedback of the input inductor L2 received between the two sense resistor loads with the first sense resistor R5 leading to ground and the second sense resistor R11 feeding to comparator to provide the output controlling drive signal in comparison to an input of a reference voltage.

5. The amplifier according to claim 4 wherein the resonant controller includes the arrangement of the first and second sense resistors loads forming a voltage summing node for the two respective signals with the first sense resistor R5 to ground detecting DC variations of input and the second sense resistor R11 feeding to comparator detecting AC fluctuations.

6. The amplifier according to claim 1 wherein the resonant controller includes first sense resistor R5 having primary role to track the desired current in L2 such that the system power is controlled.

7. The amplifier according to claim 4 wherein the resonant controller includes using ripple information on the sense resistor loads R5 due to ripple current in L2.

8. The amplifier according to claim 4 wherein the resonant controller includes first sense resistor loads R5 in combination with R11 to amplify the ripple component to ensure adequate signal strengths over the large voltage range imposed on the system by a rectified AC waveform.

9. The amplifier according to claim 8 wherein the resonant controller includes the ratios of R11 and R5 selected to allow control of the system power factor.

10. The amplifier according to claim 4 wherein the resonant controller includes matching the system resonance frequency with the digital system latencies once the AC signal is adequate.

11. The amplifier according to claim 10 wherein the matching the system resonance frequency with the digital system latencies once the AC signal is achieved by the addition of optional phase lagging RC filters.

12. The amplifier according to claim 11 wherein the matching the system resonance frequency with the digital system latencies at the output of the comparator is performed in the digital section.

13. The amplifier according to claim 4 wherein the system resonance control successfully ensures correct and regular operation 15 over 1 mains half cycle allowing the system to Zero Voltage Switches (ZVS) paramount to high speed, low loss operation.

14. The amplifier according to claim 1 further including a brake circuit having brake elements provided by arrangement of FET and resistor load R3 and transistor T3 in output of FET of amplifier and in feedback circuit to input of FET of amplifier following determination of feedback of input inductor feed such that the brake element turns off FET of brake circuit if overshoot of current allowing flow through resistor load and thereby providing stoppage means or brake for any overcurrent.

15. The amplifier according to claim 14 wherein brake circuit switching occurs only after powering off of other signal control and thereby avoiding possibility of overcurrent.

16. The amplifier according to claim 1 further including an active rectifier which uses the power control including an active rectifier of input power to guarantee FET gate is within threshold, by using a FET controller in combination with a linear regulator.

17. The amplifier according to claim 16 wherein the linear regulator incorporates a large resistor R4 of the order of 100K Ohm′ and voltage close to operative voltage of the FET so as to minimise power losses through minimising current in control switching.

18. The amplifier according to claim 16 wherein the rectifier is formed of a plurality of pairs of P and N doped MOSFETs wherein gate of one P doped MOSFETs is connected to drain of N doped MOSFET and vice versa.

19. The amplifier according to claim 18 wherein the rectifier includes a pair of pairs of NFET or PFET, wherein operation of FETs with voltages of less than 1 Volt are controlled by the rectifier.

20. The amplifier according to claim 19 wherein the rectifier includes a Zener/resistor arrangement connecting between the pair of pairs of P and N doped MOSFETs.

21. The amplifier according to claim 19 wherein the Zener is only large enough to ensure the rectifier FET is turned on, keeping the transfer of energy low.

22. The amplifier according to claim 19 wherein the MOSFETs impedance is low during the charge of the bridge MOSFET, which allows for rapid charge, but becomes very high once the Zener voltage is reached, ensuring no leakage regardless of what AC signal is on the input.

23. The amplifier according to claim 19 wherein the Zener bias resistor value can be very large, using very little energy as it is not charging the bridge MOSFET gate cap.

24. The amplifier according to claim 19 wherein, when the gate signal pulls low, D1 (Ti's body diode) discharges the bridge gate capacitance.
